(19) United States
(12) Patent Application Publication
(10) Pub. No.: US 2021/0288367 A1
(43) Pub. Date: Sep. 16, 2021

(54) VEHICLE-MOUNTABLE BATTERY UNIT

(71) Applicant: HONDA MOTOR CO., LTD., Tokyo (JP)

(72) Inventors: Shinji FUJIMOTO, Saitama (JP); Shigemitsu AKUTSU, Saitama (JP)

(21) Appl. No.: 17/190,423

(22) Filed: Mar. 3, 2021

(30) Foreign Application Priority Data
Mar. 16, 2020 (JP) 2020-045039

(51) Int. Cl. H01M 50/209; H05K 7/20; H01M 10/613; H01M 10/625; H01M 50/249

(52) U.S. Cl. CPC H01M 50/209; H05K 7/2089; H01M 2220/20; H01M 10/625; H01M 50/249; H01M 10/613

(57) ABSTRACT

The present disclosure is intended to provide a vehicle-mountable battery unit that includes a high-voltage battery and a low-voltage battery integrated with each other and that is compatible with significantly restricted installation conditions. A vehicle-mountable battery unit of the present disclosure includes a high-voltage battery constituted by a plurality of layered flat battery cells of a predetermined first specification; a low-voltage battery constituted by a plurality of layered flat battery cells of a predetermined second specification; and a support structure supporting the high-voltage battery and the low-voltage battery, as a combination battery unit into which the high and low-voltage batteries and are integrated while being insulated from each other, the support structure pressurizing the high and low-voltage batteries and as the combination battery unit in a layering direction in which the flat battery cells are layered.

This application is based on and claims the benefit of priority from Japanese Patent Application No. 2020-045039, filed on 16 Mar. 2020, the content of which is incorporated herein by reference.

### BACKGROUND OF THE INVENTION

### Field of the Invention

The present disclosure relates to a vehicle-mountable battery unit.

### Related Art

It has been proposed to form a vehicle-mountable battery unit by a process that includes forming small modules each including a plate-shaped frame and single cells retained in the frame, forming a multilayer unit by layering the small modules together in the thickness direction of the frame, and pressurizing the multilayer unit at both surfaces thereof in the layering direction by way of a heat sink, thereby integrally retaining the multilayer unit (see, for example, Patent Document 1).
Patent Document 1: Japanese Unexamined Patent Application, Publication No. 2005-116427

### SUMMARY OF THE INVENTION

The vehicle-mountable battery unit disclosed in Patent Document 1 is suitable as a high-voltage power supply for a drive motor of an electric vehicle. On the other hand, in general, the electric vehicle is also equipped with, apart from the high-voltage power supply, a relatively low-voltage battery as a power supply dedicated to auxiliary equipment such as headlights and a car navigation system. On the other hand, recently, a large number of electric devices have been mounted on a vehicle, and significant restrictions are imposed on spaces where the electric devices are installed.

In view of the above background, the present disclosure is intended to provide a vehicle-mountable battery unit that includes a high-voltage battery and a low-voltage battery integrated with each other and that is compatible with significantly restricted installation conditions.

A vehicle-mountable battery unit according to a first aspect of the present disclosure includes: a high-voltage battery (e.g., a high-voltage battery 4 to be described later) constituted by a plurality of layered flat battery cells (e.g., flat battery cells 16 to be described later) of a predetermined first specification; a low-voltage battery (e.g., a low-voltage battery 5 to be described later) constituted by a plurality of layered flat battery cells (e.g., flat battery cells 20 to be described later) of a predetermined second specification; and a support structure (e.g., a support structure 6 to be described later) supporting the high-voltage battery and the low-voltage battery, as a combination battery unit (e.g., a combination battery unit 3 to be described later) into which the high-voltage battery and the low-voltage battery are integrated while being insulated from each other, the support structure pressurizing the high-voltage battery and the low-voltage battery as the combination battery unit in a layering direction in which the flat battery cells are layered.

A second aspect of the present disclosure is an embodiment of the first aspect. In the second aspect, the first specification is identical to the second specification.

A third aspect of the present disclosure is an embodiment of the first or second aspect. In the third aspect, the support structure supports the high-voltage battery and the low-voltage battery while coupling the high-voltage battery to the low-voltage battery in the layering direction.

A fourth aspect of the present disclosure is an embodiment of any one of the first to third aspects. In the fourth aspect, the combination battery unit is provided with a DC-DC converter (e.g., a DC-DC converter 11 to be described later) for converting an output voltage of the high-voltage battery.

A fifth aspect of the present disclosure is an embodiment of the fourth aspect. In the fifth aspect, the DC-DC converter is provided with a cooling circuit (e.g., a cooling circuit 13 to be described later).

A sixth aspect of the present disclosure is an embodiment of any one of the first to fifth aspects. In the sixth aspect, the support structure includes a pair of end plates (e.g., end plate 7, 8 to be described later) that are disposed at both ends of the combination battery unit in the layering direction, and a pair of side plates (e.g., side plates 9, 10 to be described later) that connect the end plates to each other while sandwiching the combination battery unit. The side plates support the flat battery cells as constituent components of the combination battery unit such that tabs of the flat battery cells are held bent, the tabs being provided in a width direction of the flat battery cells.

A seventh aspect of the present disclosure is an embodiment of any one of the first to sixth aspects. In the seventh aspect, the combination battery unit is provided with a battery management system (BMS) (e.g., a BMS 15 to be described later) for managing a state of the combination battery unit.

An eighth aspect of the present disclosure is an embodiment of any one of the first to seventh aspects. In the eighth aspect, when the vehicle-mountable battery unit is mounted on a vehicle, the support structure supports the combination battery unit such that a positive electrode terminal (e.g., a positive-electrode output terminal 19 to be described later) of the high-voltage battery is spaced further away than a negative electrode terminal (e.g., a negative-electrode output terminal 18 to be described later) of the high-voltage battery from a body of the vehicle.

In the vehicle-mountable battery unit according to the first aspect, the support structure supports the combination battery unit into which the high-voltage battery and the low-voltage battery are integrated, while pressurizing the combination battery unit in the layering direction of the flat battery cells, which are constituent components of the combination battery unit. This feature allows the flat battery cells to sufficiently perform their function, and achieves a compact power supply unit. Thus, the vehicle-mountable battery unit according to the first aspect is satisfactorily compatible with significantly restricted installation conditions of a vehicle.

In the vehicle-mountable battery unit according to the second aspect, the flat battery cells constituting the high-voltage battery and the flat battery cells constituting the low-voltage battery are of the same specification. Thus, the high-voltage battery and the low-voltage battery can be formed respectively by connecting in series the same flat battery cells in different numbers. This feature contributes to a decrease in the number of types of parts, thereby reducing management costs of the manufacturing process.

In the vehicle-mountable battery unit according to the third aspect, the support structure supports the high-voltage battery and the low-voltage battery while coupling the high-voltage battery to the low-voltage battery in the layering direction of the flat battery cells constituting the high and low-voltage batteries. As a result, a pressing force in the layering direction acts between the flat battery cells. This feature makes the combination battery unit structurally stable.

In the vehicle-mountable battery unit according to the fourth aspect, the combination battery unit is provided with the DC-DC converter for converting an output voltage of the high-voltage battery. This feature contributes to simplification of a route of a power supply cable from the vehicle-mountable battery unit to a traction motor.

In the vehicle-mountable battery unit according to the fifth aspect, the DC-DC converter is provided with the cooling circuit, which can also serve as a cooling circuit for the batteries. This feature contributes to simplification of the cooling system.

In the vehicle-mountable battery unit according to the sixth aspect, the support structure includes the pair of end plates that are disposed at both ends of the combination battery unit in the layering direction, and the pair of side plates that connect the end plates to each other while sandwiching the combination battery unit. The side plates support the flat battery cells as constituent components of the combination battery unit such that the tabs of the flat battery cells are held bent, the tabs being provided in the width direction of the flat battery cells. With this feature, the vehicle-mountable battery unit that is compact as a whole is achieved.

In the vehicle-mountable battery unit according to the seventh aspect, the combination battery unit is provided with the battery management system (BMS) for managing a state of the combination battery unit. This feature simplifies a management system associated with the combination battery unit.

According to the eighth aspect, when the vehicle-mountable battery unit is mounted on a vehicle, the support structure supports the combination battery unit such that the positive electrode terminal of the high-voltage battery is spaced further away than the negative electrode terminal of the high-voltage battery from the body of the vehicle. At the time of maintenance, this feature reduces the risk of a short circuit in the positive-electrode output terminal of the high-voltage battery to a ground (the body of the vehicle).

### BRIEF DESCRIPTION OF THE DRAWINGS

FIG. 1 is a planar view showing a vehicle-mountable battery unit as one embodiment of the present disclosure;

FIG. 2 is a cross-sectional view of the vehicle-mountable battery unit of FIG. 1, taken along line A-A;

FIG. 3 is a cross-sectional view showing main components of a vehicle-mountable battery unit as another embodiment of the present disclosure;

FIG. 4 is a cross-sectional view showing main components of a vehicle-mountable battery unit as yet another embodiment of the present disclosure; and

FIG. 5 is a cross-sectional view showing main components of a vehicle-mountable battery unit as still yet another embodiment of the present disclosure.

### DETAILED DESCRIPTION OF THE INVENTION

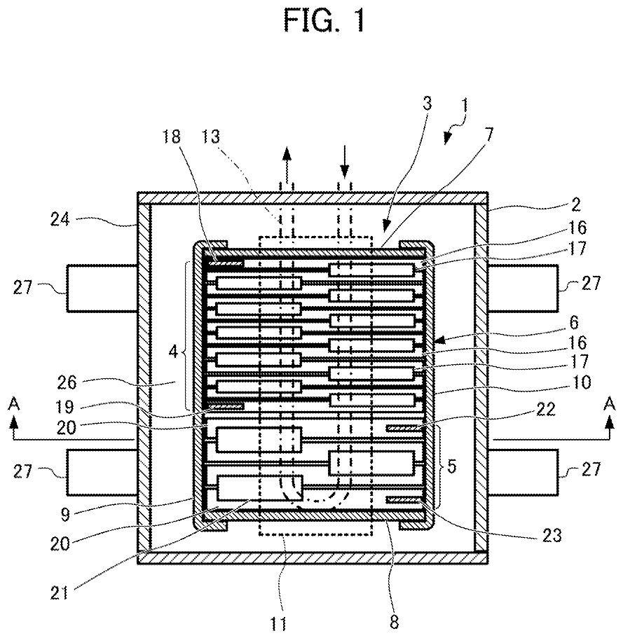

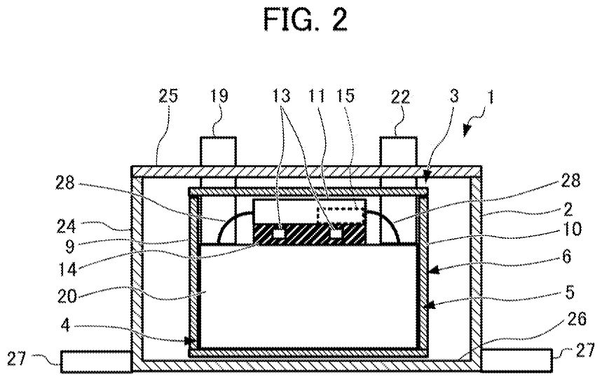

One embodiment of the present: disclosure will be described with reference to the drawings. FIG. 1 is a planar view showing a vehicle-mountable battery unit 1 as one embodiment of the present disclosure. FIG. 2 is a cross-sectional view of the vehicle-mountable battery unit 1 of FIG. 1, taken along line A-A. The vehicle-mountable battery unit 1 shown in FIGS. 1 and 2 includes a battery case 2 and a combination battery unit 3 housed in the battery case 2, as viewed in cross section. The combination battery unit 3, into which a high-voltage battery 4 and a low-voltage battery 5 are integrated while being insulated from each other, is supported and pressurized by a support structure 6 in a layering direction in which flat battery cells are layered, the flat battery cells being constituent components of the combination battery unit 3. The high-voltage battery 4 is constituted by a plurality of layered flat battery cells of a predetermined first specification. Here, the first specification refers to, for example, a laminated battery having an average voltage of several volts. Alternatively, the first specification can refer to an all-solid battery. In the case where the flat battery cells are configured as the all-solid batteries, the flat battery cells sufficiently perform their function since they are supported and pressurized in the layering direction by the support structure 6. The low-voltage battery 5 is constituted by a plurality of layered flat battery cells of a predetermined second specification. Here, the second specification refers to, for example, a battery having an average voltage of several volts, and can be the same as the first specification. The vehicle-mountable battery unit 1 is particularly configured as a vehicle-mountable battery unit for a hybrid vehicle (WV) or a hybrid electric vehicle (HEV). The high-voltage battery 4 is used mainly for driving a traction motor and the like. The low-voltage battery 5 is used as a power supply for generally-used auxiliary equipment of the vehicle.

The support structure 6 includes a pair of end plates 7, 8 that are disposed at both ends of the combination battery unit 3 in the layering direction of the flat battery cells, and a pair of side plates 9, 10 that connect the end plates 7, 8 to each other while sandwiching the combination battery unit 3. Specifically, the end plate 7 is provided at the end of the combination battery unit 3 adjacent to the high-voltage battery 4 while the end plate 8 is provided at the other end of the combination battery unit 3 adjacent to the low-voltage battery 5. The side plates 9, 10 connect the end plates 7, 8 to each other while maintaining a certain tension. As a result, the high-voltage battery 4 and the low-voltage battery 5 are supported while being pressurized by a pressing force that constantly acts in the layering direction of the flat battery cells of the high and low-voltage batteries 4 and 5. Each flat battery cell has a tab (not shown) in a width direction of the flat battery cell. The pair of side plates 9, 10 support the flat battery cells as constituent components of the combination battery unit 3 such that the tabs of the flat battery cells are held bent.

The combination battery unit 3 is provided with a DC-DC converter 11 for converting an output voltage of the high-voltage battery 4. The DC-DC converter 11 can be a so-called bi-directional DC-DC converter, which is electrically connected to two power lines to which the output voltage of the high-voltage battery 4 is applied, and converts the voltage. In FIG. 1, broken lines indicate the outer shape and the position of the DC-DC converter 11, as a projected plane of the contour of the DC-DC converter 11.

The DC-DC converter 11 is provided with a cooling circuit 13. The cooling circuit 13 is configured as a coolant circulation path provided in a thermally-conductive and electrically-insulating member 14 that is interposed between the DC-DC converter 11 and one wall surface of the combination battery unit 3 or a tab-connection surface of the combination battery unit 3. A coolant flows through the cooling circuit 13 as indicated by the arrows in FIG. 1, and exchanges heat with the help of an exterior coolant pump and an exterior heat exchanger.

The combination battery unit 3 is provided with a battery management system (BMS) 15 for managing a state of the combination battery unit 3. As conceptually shown in FIG. 2, the BMS 15 of this example is housed in the DC-DC converter 11, together with a DC-DC converter circuit. The DC-DC converter 11 and the BMS 15 may be provided on the same circuit board.

Next, with reference to FIG. 1, the configuration of the high-voltage battery 4 and the low-voltage battery 5 will be specifically described. The high-voltage battery 4 is constituted by the plurality of flat battery cells 16 that are layered together. As viewed from the viewpoint of FIG. 2, each flat battery cell 16 has a positive electrode tab (not shown) and a negative electrode tab (not shown) provided near the lateral ends of the upper edge of the flat battery cell 16. The plurality of flat battery cells 16 are connected in series to each other with connecting conductors 17 shown in FIG. 1.

Specifically, in the high-voltage battery 4, the flat battery cells 16 having the front surface facing in one direction alternate with the flat battery cells 16 having the front surface facing in a direction opposite to the one direction. When the flat battery cells 16 are layered together in this manner, the positive electrode tab of one flat battery cell 16 is positioned adjacent to the negative electrode tab of an adjacent flat battery cell 16, and the negative electrode tab of the one flat battery cell 16 is positioned adjacent to the positive electrode tab of another adjacent flat battery cell 16.

Connecting the adjacent positive and negative electrode tabs to each other with the connecting conductor 17 makes it possible to form the high-voltage battery 4 as a chain of the series-connected battery cells 16 by means of short wires (narrow conductors).

A conductor extendedly connected to the positive electrode tab of the flat battery cell 16 at the starting point of the series connection (the lowermost cell 16 in FIG. 1) functions as a positive-electrode output terminal 19 of the high-voltage battery 4 and is guided to outside of the battery case 2. A conductor extendedly connected to the negative electrode tab of the flat battery cell 16 at the end point of the series connection (the uppermost cell 16 in FIG. 1) functions as a negative-electrode output terminal 18 of the high-voltage battery 4 and is guided to outside of the battery case 2.

The low-voltage battery 5 is constituted by the plurality of flat battery cells 20 that are layered together. As viewed from the viewpoint of FIG. 2, each flat battery cell 20 has a positive electrode tab (not shown) and a negative electrode tab (not shown) provided near the lateral ends of the upper edge of the flat battery cell 20. The plurality of flat battery cells 20 are connected in series to each other with connecting conductors 21 shown in FIG. 1.

Like the high-voltage battery 4, in the high-voltage battery 5, the flat battery cells 20 having the front surface facing in one direction alternate with the flat battery cells 20 having the front surface facing in a direction opposite to the one direction. When the flat battery cells 20 are layered together in this manner, the positive electrode tab of one flat battery cell 20 is positioned adjacent to the negative electrode tab of an adjacent flat battery cell 20, and the negative electrode tab of the one flat battery cell 20 is positioned adjacent to the positive electrode tab of another adjacent flat battery cell 20.

Connecting the adjacent positive and negative electrode tabs to each other with the connecting conductor 21 makes it possible to form the low-voltage battery 5 as a chain of the series-connected battery cells 20 by means of short wires (narrow conductors).

A conductor extendedly connected to the positive electrode tab of the flat battery cell 20 at the starting point of the series connection (the uppermost cell 20 in FIG. 1) functions as a positive-electrode output terminal 22 of the low-voltage battery 5 and is guided to outside of the battery case 2. A conductor extendedly connected to the negative electrode tab of the flat battery cell 20 at the end point of the series connection (the lowermost cell 20 in FIG. 1) functions as a negative-electrode output terminal 23 of the low-voltage battery 5 and is guided to outside of the battery case 2.

In FIGS. 1 and 2, the battery case 2 of the vehicle-mountable battery unit 1 includes a battery case body 24 sealed with a lid 25. The lid 25 has through holes (not shown) through which the positive-electrode output terminal 19 and the negative-electrode output terminal 18 of the high-voltage battery 4 and the positive-electrode output terminal 22 and the negative-electrode output terminal 23 of the low-voltage battery 5 are guided to the outside. The battery case body 24 has, at appropriate positions, through holes that allows the cooling circuit 13 to communicate with exterior equipment. The battery case body 24 has a bottom 26 and legs 27 provided at four locations on the bottom 26, as shown in the figures. The legs 27 are for placing the battery case 2 at a predetermined portion of a vehicle.

As described above with reference to FIG. 2, the combination battery unit 3 is provided with the battery management system (BMS) 15. In this example, the BMS 15 includes a cell voltage sensor (CVS) for detecting a state (electromotive force) of the flat battery cells 16, 16 constituting the high-voltage battery 4. Referring to FIG. 2, lead wires 28 of the CVS extend from the flat battery cells 16, 16 and are guided into the DC-DC converter 11 housing the BMS 15.

In the case of the vehicle-mountable battery unit 1 shown in FIG. 1, when the vehicle-mountable battery unit 1 is mounted on a vehicle, the support structure 6 supports the combination battery unit 3 such that the positive-electrode output terminal 19 of the high-voltage battery 4 is spaced further away than the negative-electrode output terminal 13 of the high-voltage battery 4 from a body of the vehicle.

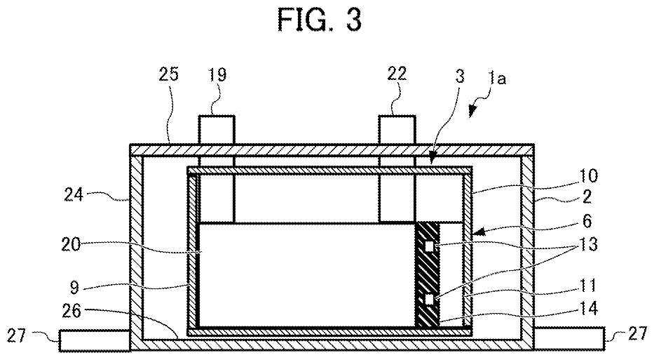

In the vehicle-mountable battery unit 1 described with reference to FIGS. 1 and 2, the positive-electrode output terminal 19 and the negative-electrode output terminal 18 of the high-voltage battery 4 of the combination battery unit 3 are guided via an upper surface of the combination battery unit 3 to the outside of the battery case 2, and the DC-DC converter 11 is provided over the upper surface of the combination battery unit 3 with interposition of the thermally-conductive and electrically-insulating member 14 that is in contact with the upper surface. However, the position of the DC-DC converter 11 is not limited to this. As will be described with reference to FIGS. 3 to 5, the position can be selected from various options.

FIGS. 3 to 5 are each a cross-sectional view showing main components of a vehicle-mountable battery unit as a different embodiment of the present disclosure, taken along a line corresponding to the line A-A in FIG. 1. In FIGS. 3 to 5, components corresponding to those shown in FIGS. 1 and 2 are denoted by the same reference numerals, and the description provided above with reference to FIGS. 1 and 2 applies to the corresponding components shown in FIGS. 3 to 5.

FIG. 3 shows a vehicle-mountable battery unit 1a, in which the DC-DC converter 11 is provided over a side surface of the combination battery unit 3 with interposition of the thermally-conductive and electrically-insulating member 14 that is in contact with the side surface, the side surface being perpendicular to a surface via which the positive-electrode output terminal 19 and the negative-electrode output terminal 18 of the high-voltage battery 4 are guided to the outside of the battery case 2.

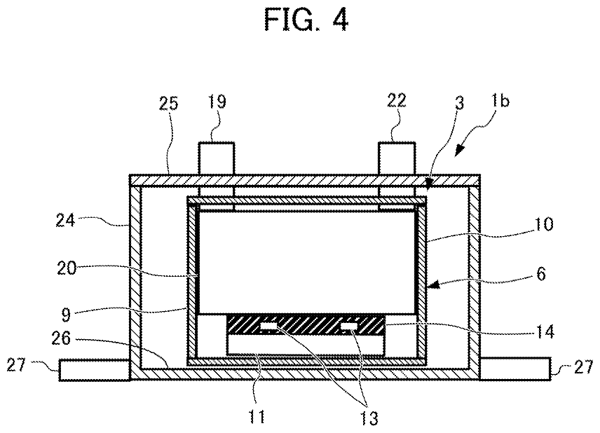

FIG. 4 shows a vehicle-mountable battery unit 1b, in which the DC-DC converter 11 is provided over a bottom surface of the combination battery unit 3 with interposition of the thermally-conductive and electrically-insulating member 14 that is in contact with the bottom surface, the bottom surface being opposite to a surface via which the positive-electrode output terminal 19 and the negative-electrode output terminal 18 of the high-voltage battery 4 are guided to the outside of the battery case 2.

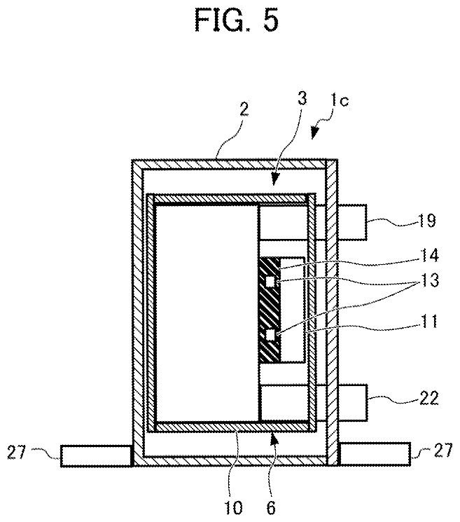

FIG. 5 shows a vehicle-mountable battery unit 1c, in which the battery case 2 that houses the combination battery unit. 3 has the legs 27 provided at one end in the longitudinal direction of a cross section of the battery case 2. As a result, the battery case 2 has a relatively large height from a relatively small projection plane on a mounting surface of a vehicle body with which the legs 27 are supposed to contact. As shown in FIG. 5, in the vehicle-mountable battery unit 1c, the DC-DC converter 11 is provided over a surface of the combination battery unit 3 with interposition of the thermally-conductive and electrically-insulating member 14 that is in contact with the surface, the surface being parallel to a side surface of the battery case 2 via which the positive-electrode output terminal 19 and the negative-electrode output terminal 18 of the high-voltage battery 4 are guided to the outside of the battery case 2.

The vehicle-mountable battery unit of the present embodiment exerts the following effects.

In the vehicle-mountable battery unit 1 according to the first aspect, the support structure 6 supports the combination battery unit 3 into which the high-voltage battery 4 and the low-voltage battery 5 are integrated, while pressurizing the combination battery unit 3 in the layering direction of the flat battery cells 16, 20, which are constituent components of the combination battery unit 3. This feature allows the flat battery cells 16, 20, to sufficiently perform their function, and achieves a compact power supply unit. Thus, the vehicle-mountable battery unit 1 according to the first aspect is satisfactorily compatible with significantly restricted installation conditions of a vehicle.

In the vehicle-mountable battery unit 1 according to the second aspect, the flat battery cells 16 constituting the high-voltage battery 4 and the flat battery cells 20 constituting the low-voltage battery 5 are of the same specification. Thus, the high-voltage battery 4 and the low-voltage battery 5 can be formed respectively by connecting in series the same flat battery cells in different numbers. This feature contributes to a decrease in the number of types of parts, thereby reducing management costs of the manufacturing process.

In the vehicle-mountable battery unit according to the third aspect, the support structure 6 supports the high-voltage battery 4 and the low-voltage battery 5 while coupling the high-voltage battery 4 to the low-voltage battery 5 in the layering direction of the flat battery cells 16, 20 constituting the high and low-voltage batteries. As a result, a pressing force in the layering direction acts between the flat battery cells. This feature makes the combination battery unit 3 structurally stable.

In the vehicle-mountable battery unit according to the fourth aspect, the combination battery unit 3 is provided with the DC-DC converter 11 for converting an output voltage of the high-voltage battery 4. This feature contributes to simplification of a route of a power supply cable from the vehicle-mountable battery unit 1 to a traction motor.

In the vehicle-mountable battery unit 1 according to the fifth aspect, the DC-DC converter 11 is provided with the cooling circuit 13, which can also serve as a cooling circuit for the combination battery unit 3. This feature contributes to simplification of the cooling system.

In the vehicle-mountable battery unit 1 according to the sixth aspect, the support structure 6 includes the pair of end plates 7, 8 that are disposed at both ends of the combination battery unit 3 in the layering direction, and the pair of side plates 9, 10 that connect the end plates 7, 8 to each other while sandwiching the combination battery unit 3. The side plates 9, 10 support the flat battery cells 16, 20 as constituent components of the combination battery unit 3 such that the tabs of the flat battery cells 16, 20 are held bent, the tabs being provided in a width direction of the flat battery cells. With this feature, the vehicle-mountable battery unit that is compact as a whole is achieved.

In the vehicle-mountable battery unit 1 according to the seventh aspect, the combination battery unit 3 is provided with the battery management system (BMS) 15 for managing a state of the combination battery unit 3. This feature simplifies a management system associated with the combination battery unit 3.

According to the eighth aspect, when the vehicle-mountable battery unit 1 is mounted on a vehicle, the support structure 6 supports the combination battery unit 3 such that the positive-electrode output terminal 19 of the high-voltage battery 4 is spaced further away than the negative-electrode output terminal 18 of the high-voltage battery 4 from the body of the vehicle. At the time of maintenance, this feature reduces the risk of a short circuit in the positive-electrode output terminal 19 of the high-voltage battery 4 to a ground (the body of the vehicle).

In the foregoing, the embodiments of the present disclosure have been described. However, the present disclosure is not limited to the above embodiments. The specifics of the configuration may be modified as appropriate, without deviating from the spirit of the present disclosure. For example, in the case shown in FIG. 1, the high-voltage battery 4 is constituted by a chain of the series-connected flat battery cells. However, a high-voltage battery with a large capacity may be formed by connecting in parallel a plurality of such chains of series-connected flat battery cells.

### EXPLANATION OF REFERENCE NUMERALS

1: Vehicle-Mountable Battery Unit
2: Battery Case
3: Combination Battery Unit
4: High-Voltage Battery
5: Low-Voltage Battery
6: Support Structure
7, 8: End Plate
9, 10: Side Plate
11: DC-DC Converter
13: Cooling Circuit
14: Thermally-Conductive and Electrically-Insulating Member
15: Battery Management System (BMS)
16: Flat Battery Cell
17: Connecting Conductor
18: Negative-Electrode Output Terminal
19: Positive-Electrode Output Terminal
20: Flat Battery Cell
21: Connecting Conductor
22: Positive-Electrode Output Terminal
23: Negative-Electrode Output Terminal
24: Battery Case Body
25: Lid
26: Bottom
27: Leg
28: Lead Wire

What is claimed is:

1. A vehicle-mountable battery unit comprising:
a high-voltage battery constituted by a plurality of layered flat battery cells of a predetermined first specification;
a low-voltage battery constituted by a plurality of layered flat battery cells of a predetermined second specification; and
a support structure supporting the high-voltage battery and the low-voltage battery, as a combination battery unit into which the high-voltage battery and the low-voltage battery are integrated while being insulated from each other, the support structure pressurizing the high-voltage battery and the low-voltage battery as the combination battery unit in a layering direction in which the flat battery cells are layered.

2. The vehicle-mountable battery unit according to claim 1,
wherein the first specification is identical to the second specification.

3. The vehicle-mountable battery unit according to claim 1,
wherein the support structure supports the high-voltage battery and the low-voltage battery while coupling the high-voltage battery to the low-voltage battery in the layering direction.

4. The vehicle-mountable battery unit according to claim 1,
wherein the combination battery unit is provided with a DC-DC converter for converting an output voltage of the high-voltage battery.

5. The vehicle-mountable battery unit according to claim 4,
wherein the DC-DC converter is provided with a cooling circuit.

6. The vehicle-mountable battery unit according to claim 1,
wherein the support structure includes a pair of end plates that are disposed at both ends of the combination battery unit in the layering direction, and a pair of side plates that connect the end plates to each other while sandwiching the combination battery unit, and
wherein the side plates support the flat battery cells as constituent components of the combination battery unit such that tabs of the flat battery cells are held bent, the tabs being provided in a width direction of the flat battery cells.

7. The vehicle-mountable battery unit according to claim 1,
wherein the combination battery unit is provided with a battery management system (BMS) for managing a state of the combination battery unit.

8. The vehicle-mountable battery unit according to claim 1,
wherein when the vehicle-mountable battery unit is mounted on a vehicle, the support structure supports the combination battery unit such that a positive electrode terminal of the high-voltage battery is spaced further away than a negative electrode terminal of the high-voltage battery from a body of the vehicle.

9. The vehicle-mountable battery unit according to claim 2,
wherein the support structure supports the high-voltage battery and the low-voltage battery while coupling the high-voltage battery to the low-voltage battery in the layering direction.

10. The vehicle-mountable battery unit according to claim 2,
wherein the combination battery unit is provided with a DC-DC converter for converting an output voltage of the high-voltage battery.

11. The vehicle-mountable battery unit according to claim 3,
wherein the combination battery unit is provided with a DC-DC converter for converting an output voltage of the high-voltage battery.

12. The vehicle-mountable battery unit according to claim 9,
wherein the combination battery unit is provided with a DC-DC converter for converting an output voltage of the high-voltage battery.

13. The vehicle-mountable battery unit according to claim 10,
wherein the DC-DC converter is provided with a cooling circuit.

14. The vehicle-mountable battery unit according to claim 11,
wherein the DC-DC converter is provided with a cooling circuit.

15. The vehicle-mountable battery unit according to claim 12,
wherein the DC-DC converter is provided with a cooling circuit.

16. The vehicle-mountable battery unit according to claim 2,
wherein the support structure includes a pair of end plates that are disposed at both ends of the combination battery unit in the layering direction, and a pair of side plates that connect the end plates to each other while sandwiching the combination battery unit, and
wherein the side plates support the flat battery cells as constituent components of the combination battery unit such that tabs of the flat battery cells are held bent, the tabs being provided in a width direction of the flat battery cells.

17. The vehicle-mountable battery unit according to claim 3,
wherein the support structure includes a pair of end plates that are disposed at both ends of the combination battery unit in the layering direction, and a pair of side plates that connect the end plates to each other while sandwiching the combination battery unit, and
wherein the side plates support the flat battery cells as constituent components of the combination battery unit such that tabs of the flat battery cells are held bent, the tabs being provided in a width direction of the flat battery cells.

18. The vehicle-mountable battery unit according to claim 9,
wherein the support structure includes a pair of end plates that are disposed at both ends of the combination battery unit in the layering direction, and a pair of side plates that connect the end plates to each other while sandwiching the combination battery unit, and
wherein the side plates support the flat battery cells as constituent components of the combination battery unit such that tabs of the flat battery cells are held bent, the tabs being provided in a width direction of the flat battery cells.

19. The vehicle-mountable battery unit according to claim 4,
wherein the support structure includes a pair of end plates that are disposed at both ends of the combination battery unit in the layering direction, and a pair of side plates that connect the end plates to each other while sandwiching the combination battery unit, and
wherein the side plates support the flat battery cells as constituent components of the combination battery unit such that tabs of the flat battery cells are held bent, the tabs being provided in a width direction of the flat battery cells.

20. The vehicle-mountable battery unit according to claim 10,
wherein the support structure includes a pair of end plates that are disposed at both ends of the combination battery unit in the layering direction, and a pair of side plates that connect the end plates to each other while sandwiching the combination battery unit, and
wherein the side plates support the flat battery cells as constituent components of the combination battery unit such that tabs of the flat battery cells are held bent, the tabs being provided in a width direction of the flat battery cells.
